(19) United States
(12) Patent Application Publication
(10) Pub. No.: US 2025/0364046 A1
(43) Pub. Date: Nov. 27, 2025

(54) MEMORY DEVICE

(71) Applicant: SK hynix Inc., Icheon-si Gyeonggi-do (KR)

(72) Inventors: Seok Joon KANG, Icheon-si Gyeonggi-do (KR); Jun Ho CHEON, Icheon-si Gyeonggi-do (KR)

(73) Assignee: SK hynix Inc., Icheon-si Gyeonggi-do (KR)

(21) Appl. No.: 18/904,197

(22) Filed: Oct. 2, 2024

(30) Foreign Application Priority Data
May 22, 2024 (KR) 10-2024-0066540

(51) Int. Cl. G11C 13/00

(52) U.S. Cl. CPC G11C 13/0028; G11C 13/0026; G11C 13/004

(57) ABSTRACT

A memory device includes a memory cell array and a regulator. The memory cell array includes a plurality of memory cells arranged in areas in which word lines and bit lines intersect with source lines, the word lines and the bit lines extending in a first direction and the source lines extending in the second direction. Memory cells along the first direction, among the plurality of memory cells, are electrically coupled to a same word line and a same bit line, memory cells along the second direction, among the plurality of memory cells, are electrically coupled to a same source line, and the bit lines are shunted at one or more shunt nodes. The regulator applies a bit line voltage to a common node at which the bit lines are electrically coupled in common.

### CROSS-REFERENCES TO RELATED APPLICATION

The present application claims priority under 35 U.S.C. §119(a) to Korean patent application number 10-2024-0066540 filed on May 22, 2024, in the Korean Intellectual Property Office, which application is incorporated herein by reference in its entirety.

BACKGROUND 1. TECHNICAL FIELD

Various embodiments generally relate to a semiconductor device, and, more particularly, to a memory device that performs computational operations.

2. RELATED ART

Electronic devices include many electronic components, and among them, a computer system may include many electronic components composed of semiconductors. Among the semiconductor devices constituting the computer system, a host device, such as a processor or a memory controller, can perform data communication with a memory device. The memory device may include a plurality of memory cells, which may be specified by word lines and bit lines, to store data.

In recent years, techniques have been developed to utilize the memory device for computational operations to improve the performance of data processing. When data is not sent to a CPU and the memory device computes directly internally, delays due to data movement can be reduced and energy efficiency can be increased.

SUMMARY

In an embodiment, a memory device may include a memory cell array and a regulator. The memory cell array may include a plurality of memory cells arranged in areas in which word lines and bit lines intersect with source lines, the word lines and the bit lines extending in a first direction and the source lines extending in the second direction. Memory cells along the first direction, among the plurality of memory cells, may be electrically coupled to a same word line and a same bit line, memory cells along the second direction, among the plurality of memory cells, may be electrically coupled to a same source line, and the bit lines may be shunted at one or more shunt nodes. The regulator may be configured to apply a bit line voltage to a common node at which the bit lines are electrically coupled in common.

In an embodiment, a memory device may include a memory cell array, a first regulator and a second regulator. The memory cell array may include a plurality of memory cells arranged in areas in which word lines and bit lines intersect with source lines, the word lines and the bit lines extending in a first direction and the source lines extending in the second direction. Memory cells along the first direction, among the plurality of memory cells, may be electrically coupled to a same word line and a same bit line, and memory cells along the second direction, among the plurality of memory cells, may be electrically coupled to a same source line. The first regulator may be configured to apply a bit line voltage to a first common node at which first bit lines of the bit lines are electrically coupled. The second regulator may be configured to apply the bit line voltage to a second common node at which second bit lines of the bit lines are electrically coupled.

In an embodiment, a memory device may include a memory cell array and a control logic. The memory cell array may include a plurality of memory cells arranged in areas in which word lines and bit lines intersect with source lines, the word lines and the bit lines extending in a first direction and the source lines extending in the second direction. Memory cells along the first direction, among the plurality of memory cells, may be electrically coupled to a same word line and a same bit line, and memory cells along the second direction, among the plurality of memory cells, may be electrically coupled to a same source line. The control logic may be configured to perform a MAC operation on one or more first input values and one or more second input values by storing the first input values in one or more target memory cells electrically coupled to a target word line, among the word lines.

### BRIEF DESCRIPTION OF THE DRAWINGS

FIG. 1 is a block diagram illustrating a memory device according to an embodiment of the present disclosure.

FIG. 2 is a circuit diagram illustrating a configuration of a bit line control circuit of FIG. 1 according to an embodiment of the present disclosure.

FIGS. 3 and 4 are diagrams to illustrate how the memory device of FIG. 1 performs a MAC operation according to an embodiment of the present disclosure.

FIG. 5 is a block diagram illustrating a memory device according to an embodiment of the present disclosure.

FIG. 6 is a diagram to illustrate how the memory device of FIG. 5 performs a MAC operation according to an embodiment of the present disclosure.

FIG. 7 is a block diagram illustrating a memory device according to an embodiment of the present disclosure.

FIG. 8 is a diagram to illustrate how the memory device of FIG. 7 performs a MAC operation according to an embodiment of the present disclosure.

### DETAILED DESCRIPTION

Various embodiments of the present disclosure can perform computational operations with improved accuracy.

Hereinafter, embodiments of the present disclosure will be described in more detail with reference to the accompanying drawings.

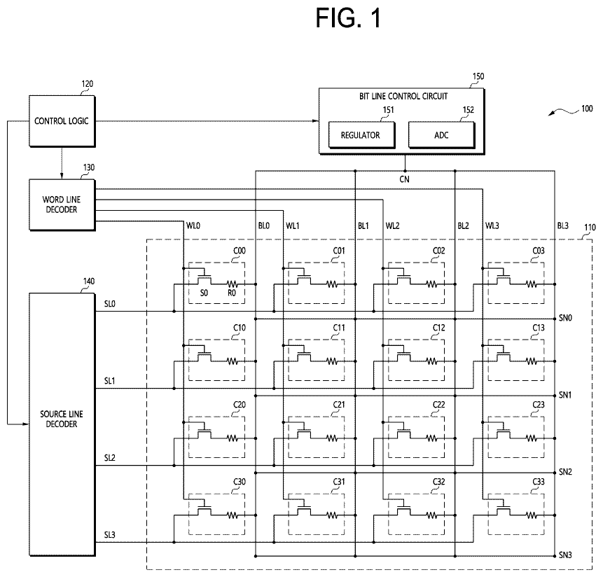

FIG. 1 is a block diagram illustrating a memory device 100 according to an embodiment of the present disclosure.

Referring to FIG. 1, the memory device 100 may operate under the control of an external device from the memory device 100. Specifically, the memory device 100 may store data and output the stored data to the external device. Further, the memory device 100 may perform a multiply accumulate (MAC) operation on data transmitted from the external device.

The memory device 100 may include a memory cell array 110, a control logic 120, a word line decoder 130, a source line decoder 140, and a bit line control circuit 150. Each of the control logic 120, the word line decoder 130, the source line decoder 140, and the bit line control circuit 150 may comprise hardware, such as circuits and memory, software, firmware, or a combination thereof.

The memory cell array 110 may include memory cells C00 to C33 arranged in areas in which word lines WL0 to WL3 and bit lines BL0 to BL3 intersect with source lines SL0 to SL3. The word lines WL0 to WL3 and the bit lines BL0 to BL3 may extend in a first direction and the source lines SL0 to SL3 may extend in a second direction, the second direction being substantially perpendicular to the first direction. The word lines WL0 to WL3 and the bit lines BL0 to BL3 may alternately extend in the first direction. A first word line and a first bit line adjacent to each other may form a pair, a second word line and a second bit line adjacent to each other may form another pair, and so forth. The source lines SL0 to SL3 may extend in the second direction intersecting the first direction. The number of word lines WL0 to WL3, bit lines BL0 to BL3, and source lines SL0 to SL3, shown in FIG. 1, are exemplary and may vary.

The memory cells listed in the first direction may be electrically coupled to a corresponding word line and a corresponding bit line. For example, the memory cells C00, C10, C20, and C30, listed in the first direction, may be electrically coupled to the word line WL0 and the bit line BL0.

The memory cells listed in the second direction may be electrically coupled to a corresponding source line. For example, the memory cells C00, C01, C02, and C03, listed in the second direction, may be electrically coupled to the source line SL0.

The bit lines BL0 to BL3 may be electrically coupled in common to a common node CN. The bit lines BL0 to BL3 may be directly coupled to the common node CN without any switches. As such, IR drop (i.e., voltage drop that occurs when current passes through a resistor) may be suppressed at the common node CN, as will be described in more detail below.

Additionally, the bit lines BL0 to BL3 may be shunted at shunt nodes SN0 to SN3 within the memory cell array 110. The shunt nodes SN0 to SN3 may be spaced apart at regular distance intervals. In an embodiment, the number of shunt nodes SN0 to SN3 may be the same as the number of source lines SL0 to SL3. The shunt nodes SN0 to SN3 may correspond to the source lines SL0 to SL3, respectively, and in an embodiment, each of the shunt nodes SN0 to SN3 may be located relatively close to the corresponding source line. Thus, in a MAC operation, current paths may be formed in parallel on all bit lines BL0 to BL3, and overall resistance along the current paths may be reduced, and thus, the IR drop may be further suppressed. The number of shunt nodes is not limited to what is illustrated in FIG. 1 and may vary.

Each of the memory cells C00 to C33 may include a variable resistor element and a switch element. For example, the memory cell C00 may include a variable resistor element R0 and a switch element S0. An end (or, first electrode) of the variable resistor element R0 may be electrically coupled to a corresponding bit line BL0. A switch element S0 may be electrically coupled between the other end (or, second electrode) of the variable resistor element R0 and a corresponding source line SL0, and the switch element S0 may be operable in response to a voltage of a corresponding word line WL0.

Each of the memory cells C00 to C33 may be accessed by controlling a corresponding word line, a corresponding bit line, and a corresponding source line. Each of the memory cells C00 to C33 may store data corresponding to a changed resistance as the resistance of the variable resistor element is changed by a program voltage applied through a corresponding word line or a corresponding bit line. For example, a variable resistor element of a memory cell in which a first value (i.e., 1) is stored may be in a low resistance state, and a variable resistor element of a memory cell in which a second value (i.e., 0) is stored may be in a high resistance state. Depending on whether the variable resistance element is in a high resistance state or a low resistance state, the amount of current (i.e., cell current) flowing through the memory cell may be different so that the data stored in the memory cell can be read based on the amount of cell current during a read operation.

In an embodiment, the memory cell may be implemented as, but is not limited to, a phase change random access memory (PRAM) cell, a resistance random access memory (RRAM) cell, a magnetic random access memory (MRAM) cell, a ferroelectric random access memory (FRAM) cell.

In an embodiment, the variable resistance element may include, but is not limited to, phase-change materials, perovskite compounds, transition metal oxides, magnetic materials, ferromagnetic materials, or antiferromagnetic materials.

The control logic 120 may control other components within the memory device 100 in response to the external device. For example, the control logic 120 may control other components within the memory device 100 to perform program operations, read operations, and the like.

To perform a MAC operation on one or more first input values and one or more second input values, the control logic 120 may store the first input values in target memory cells electrically coupled to a target word line among the word lines WL0 to WL3, respectively.

Then, the control logic 120 may control the source line decoder 140 to apply source line voltages corresponding to the second input values to the source lines SL0 to SL3, respectively, in the MAC operation. Further, the control logic 120 may control a regulator 151 to apply a bit line voltage to the common node CN in the MAC operation. Further, the control logic 120 may control the word line decoder 130 to apply a selection voltage to the target word line in the MAC operation. The control logic 120 may control the word line decoder 130 to apply a non-selection voltage to each of remaining word lines while applying the selection voltage to the target word line. As cell current flows through each of the target memory cells in response to the source line voltage, the bit line voltage, and the selection voltage, the control logic 120 may control an analog-to-digital converter (ADC) 152 to output a digital value corresponding to a cumulative cell current amount of the target memory cells as a result of the MAC operation. The cumulative cell current amount may be the total sum of the cell current amounts of the target memory cells.

The word line decoder 130 may apply predetermined voltages to the word lines WL0 to WL3 under the control of the control logic 120. The word “predetermined” as used herein with respect to a parameter, such as a predetermined timing, time, or voltage level, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm. Specifically, the word line decoder 130 may apply a selection voltage to a target word line, among the word lines WL0 to WL3, in a MAC operation. The selection voltage may be a voltage that can turn on a switch element included in each memory cell. The word line decoder 130 may apply a non-selection voltage to word lines WL0 to WL3 that are not the target word line in the MAC operation. The non-selection voltage may be a voltage that can turn off a switch element included in each memory cell. In an embodiment, the non-selection voltage may be a ground voltage. Although not shown, the word line decoder 130 may include switches electrically coupled to each of the word lines WL0 to WL3 and may individually control the word lines WL0 to WL3 through the switches.

The source line decoder 140 may apply predetermined voltages to the source lines SL0 to SL3 under the control of the control logic 120. Specifically, the source line decoder 140 may apply a first source line voltage to a corresponding source line when the second input value corresponding to a source line in a MAC operation is, for example, the first value (i.e., 1). In an embodiment, the first source line voltage may be a ground voltage. The source line decoder 140 may apply a second source line voltage to a corresponding source line when the second input value corresponding to a source line in a MAC operation is, for example, the second value (i.e., 0). The second source line voltage may be a voltage that is higher than the ground voltage. In an embodiment, the second source line voltage may be equal to the bit line voltage. Although not shown, the source line decoder 140 may include switches electrically coupled to each of the source lines SL0 to SL3 and may individually control the source lines SL0 to SL3 through the switches.

The bit line control circuit 150 may be electrically coupled to the common node CN and may perform operations on the bit lines BL0 to BL3 under the control of the control logic 120. The bit line control circuit 150 may include the regulator 151 and the analog-to-digital converter 152. The regulator 151 may apply the bit line voltage to the common node CN in a MAC operation. The analog-to-digital converter 152 may sense the cumulative cell current amount of target memory cells flowing through bit lines BL0 to BL3 in the MAC operation and may output a digital value corresponding to the cumulative cell current amount as a result of the MAC operation.

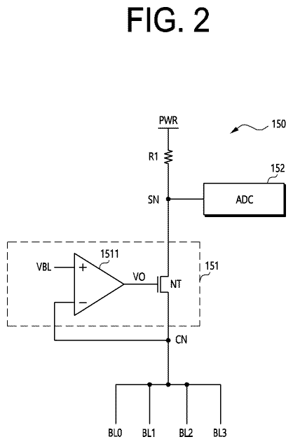

FIG. 2 is a circuit diagram illustrating a configuration of the bit line control circuit 150 of FIG. 1 according to an embodiment of the present disclosure.

Referring to FIG. 2, the bit line control circuit 150 may include the regulator 151, the analog-to-digital converter 152, and a resistor R1.

The regulator 151 may include an operational amplifier 1511 and an NMOS transistor NT. The operational amplifier 1511 may receive a bit line voltage VBL at a non-inverting input terminal and may receive a voltage of the common node CN at an inverting input terminal. The operational amplifier 1511 may output an output voltage VO in response to the bit line voltage VBL and the voltage of the common node CN. A gate of the NMOS transistor NT may be connected to an output terminal of the operational amplifier 1511 and may operate in response to the output voltage VO. A drain of the NMOS transistor NT may be connected to a sensing node SN, and a source of the NMOS transistor NT may be connected to the common node CN.

The analog-to-digital converter 152 may be electrically coupled to the sensing node SN.

The resistor R1 may be located between a voltage node PWR and the sensing node SN.

The operational amplifier 1511 may increase the output voltage VO based on a difference between the bit line voltage VBL and the voltage of the common node CN when the current flowing in the bit lines BL0 to BL3 causes an IR drop at the common node CN. In response to the increased output voltage VO, the NMOS transistor NT may pass current from the sensing node SN to the common node CN such that the voltage of the common node CN rises. Thus, the voltage of the bit lines BL0 to BL3 electrically coupled to the common node CN may be kept constant at the voltage level of the bit line voltage VBL.

The memory device 100 might not include switches between the regulator 151 and the bit lines BL0 to BL3 to individually control the bit lines BL0 to BL3. The regulator 151 may apply the bit line voltage VBL to the bit lines BL0 to BL3, in common, through the common node CN.

In a MAC operation, when cell current flows through each of the target memory cells, the cumulative cell current may flowing through the common node CN and the sensing node SN of the target memory cells. The analog-to-digital converter 152 may output a digital value corresponding to the amount of the cumulative cell current flowing to the sensing node SN as a result of the MAC operation. The amount of cumulative cell current may be the amount of cumulative cell current flowing to the sensing node SN as a result of selectively allowing cell current to flow from each of the target memory cells.

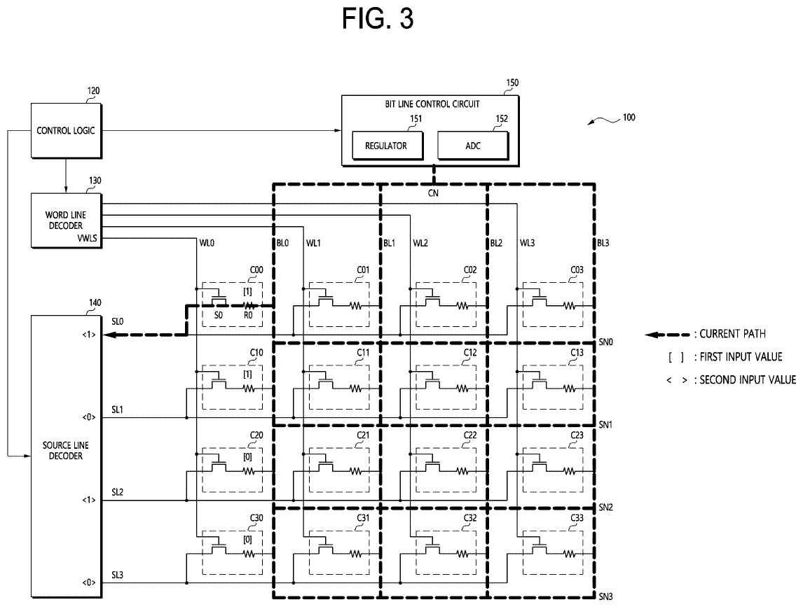

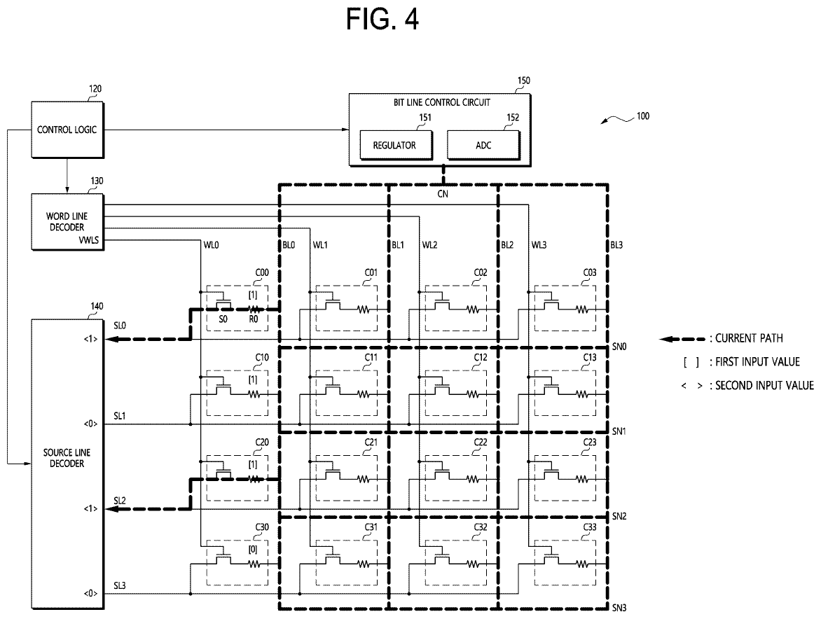

FIGS. 3 and 4 are diagrams to illustrate how the memory device 100 of FIG. 1 may perform a MAC operation according to an embodiment of the present disclosure.

Referring to FIG. 3, the control logic 120 may perform a MAC operation on the first input values and the second input values by controlling the word line decoder 130, the source line decoder 140, and the bit line control circuit 150. A target word line for the MAC operation may be a word line WL0, and target memory cells may be memory cells C00, C10, C20, and C30 electrically coupled to the word line WL0.

First, the control logic 120 may control the word line decoder 130 and the bit line control circuit 150 to store the first input values in the memory cells C00, C10, C20, and C30, respectively. The variable resistor element of each of the memory cells C00, C10, C20, and C30 may vary in resistance to store a corresponding first input value. For example, to store a first input value of “1” in each of the memory cells C00 and C10, the variable resistor element of each of the memory cells C00 and C10 may be in a low resistance state. For example, to store a first input value of “0” for each of the memory cells

C20 and C30, the variable resistor element of each of the memory cells C20 and C30 may be in a high resistance state.

The source line decoder 140 may, under the control of the control logic 120, apply voltages corresponding to the second input values to the source lines SL0 to SL3, respectively. For example, when the second input value corresponding to each of the source lines SL0 and SL2 is “1”, the source line decoder 140 may apply a first source line voltage (e.g., ground voltage) to each of the source lines SL0 and SL2. When the second input value corresponding to each of the source lines SL1 and SL3 is “0”, the source line decoder 140 may apply a second source line voltage to the source lines SL1 and SL3, respectively.

The regulator 151 may apply the bit line voltage VBL to the common node CN under the control of the control logic 120.

The word line decoder 130 may apply a selection voltage VWLS to the word line WL0. Accordingly, the switch elements of the memory cells C00, C10, C20, and C30 electrically coupled to the word line WL0 may be turned on. Each of the memory cells C00, C10, C20, and C30 may enable or disable the cell current to flow depending on the stored first input value and the second input value of the corresponding source line, i.e., depending on the state of the variable resistor element of the memory cell and the voltage of the corresponding source line. The bit lines BL0 to BL3 may form current paths in parallel to one or more selected source lines of the source lines SL0 to SL3 (i.e., source lines to which the first source line voltage is applied) in response to the bit line voltage VBL.

Specifically, because the variable resistor element R0 included in the memory cell C00 is in a low resistance state and the first source line voltage is applied to the source line SL0 electrically coupled to the memory cell C00, the memory cell C00 may allow cell current to flow. At this time, the bit lines BL0 to BL3 may be shunted so that the current path through the memory cell C00 to the source line SL0 is formed in parallel to all the bit lines BL0 to BL3 to facilitate current flow, and the overall resistance on the current path may be reduced.

On the other hand, because the second source line voltage is applied to the source line SL1 electrically coupled to the memory cell C10, the memory cell C10 might not allow cell current to flow. Also, because the variable resistance element included in the memory cell C20 is in a high resistance state, the memory cell C20 might not allow the cell current to flow. Also, because the variable resistor element included in the memory cell C30 is in a high resistance state and the second source line voltage is applied to the source line SL3 electrically coupled to the memory cell C30, the memory cell C30 might not allow the cell current to flow.

When the memory cells C00, C10, C20, and C30 each operate in this manner, the cumulative cell current amount of the sensing node SN may be equal to the cell current amount of the memory cell C00. The analog-to-digital converter 152 may output a digital value corresponding to the cumulative cell current amount of the sensing node SN as a result of the MAC operation on the first and second input values shown.

Referring to FIG. 4, based on the first input value of “1”, the variable resistance element included in the memory cell C20 may be in a low resistance state. Based on the second input value of “1”, a first source line voltage may be applied to the source line SL2 electrically coupled to the memory cell C20. Thus, the memory cell C20 may allow the cell current to flow. Further, as described with reference to FIG. 3, the memory cell C00 may also flow cell current.

When each of the memory cells C00 and C20 flows cell current, the cumulative cell current amount of the sensing node SN may be equal to the sum of the cell current amounts of the memory cells C00 and C20. The analog-to-digital converter 152 may output a digital value corresponding to the cumulative cell current amount of the sensing node SN as a result of the MAC operation on the first and second input values shown.

On the other hand, as the size of the memory cell array 110 increases, the amount of cumulative cell current in a MAC operation may increase. When a large amount of cumulative cell current flows, IR drop may occur at the common node CN due to the numerous resistors in the memory cell array 110. The IR drop at the common node CN may affect the amount of each cell current and thus cause errors in the cumulative cell current. However, according to the present disclosure, no switches (i.e., resistors) are included between the regulator 151 and the bit lines BL0 to BL3, so the IR drop may be suppressed compared to the case where the switches are present. Furthermore, the bit lines BL0 to BL3 may be shunted, thereby reducing the resistance in the current path, further suppressing the IR drop. Thus, the accuracy of the MAC operation of the memory device 100 may be improved because an error in the cumulative cell current amount is minimized.

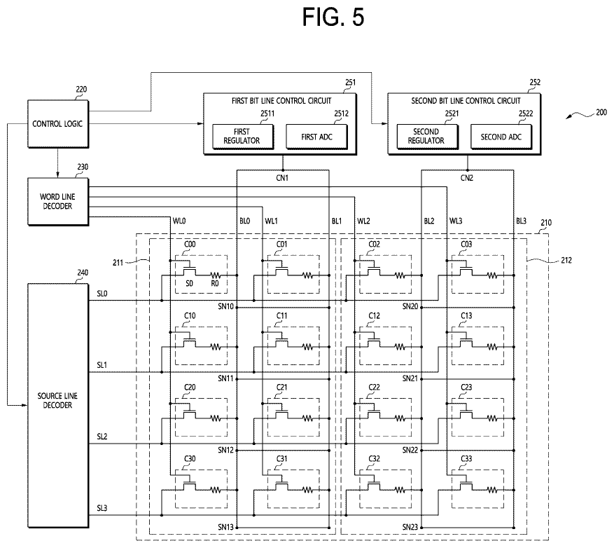

FIG. 5 is a block diagram illustrating a memory device 200 according to an embodiment of the present disclosure.

Referring to FIG. 5, the memory device 200 may include a memory cell array 210, a control logic 220, a word line decoder 230, a source line decoder 240, a first bit line control circuit 251, and a second bit line control circuit 252.

The memory cell array 210 may be configured similarly to the memory cell array 110 of FIG. 1. However, the bit lines BL0 and BL1 electrically coupled to a first common node CN1 may be shunted through first shunt nodes SN10 to SN13, and the bit lines BL2 and BL3 electrically coupled to a second common node CN2 may be shunted through second shunt nodes SN20 to SN23. The memory cells C00, C10, C20, and C30 electrically coupled to the bit line BL0 and the memory cells C01, C11, C21, and C31 electrically coupled to the bit line BL1 may be included in a first sub-memory cell array 211. The memory cells C02, C12, C22, and C32 electrically coupled to the bit line BL2 and the memory cells C03, C13, C23, and C33 electrically coupled to the bit line BL3 may be included in a second sub-memory cell array 212.

The control logic 220 may control a MAC operation for the first sub-memory cell array 211 and a MAC operation for the second sub-memory cell array 212 in parallel. Each MAC operation for each sub-memory cell array may be performed similarly to the MAC operation for the memory cell array 110 of FIG. 1.

Specifically, the control logic 220 may select a first target word line from the word lines WL0 and WL1 electrically coupled to the first sub-memory cell array 211 and a second target word line from the word lines WL2 and WL3 electrically coupled to the second sub-memory cell array 212. Further, the control logic 220 may store first input values corresponding to first target memory cells electrically coupled to the first target word line, respectively, and first input values corresponding to second target memory cells electrically coupled to the second target word line, respectively.

The control logic 220 may then control the source line decoder 240 to apply source line voltages corresponding to the second input values to the source lines SL0 to SL3. Further, the control logic 220 may control a first regulator 2511 and a second regulator 2521 to apply a bit line voltage to the first common node CN1 and the second common node CN2, respectively. Further, the control logic 220 may control the word line decoder 230 to apply a selection voltage to the first and second target word lines, respectively. The control logic 220 may control the word line decoder 230 to apply a non-selection voltage to each of remaining word lines while applying the selection voltage to the first and second target word lines. The control logic 220 may then control a first analog-to-digital converter 2512 to output a digital value corresponding to a first cumulative cell current amount of the first target memory cells as a first result of a MAC operation and may control a second analog-to-digital converter 2512 to output a digital value corresponding to a second cumulative cell current amount of the second target memory cells as a second result of a MAC operation.

Each of the first and second bit line control circuits 251 and 252 may be configured and operate similarly to the bit line control circuit 150 of FIG. 1.

The word line decoder 230 and the source line decoder 240 may be configured and operated similarly to the word line decoder 130 and the source line decoder 140, respectively, of FIG. 1.

Thus, the memory device 200 may provide improved computational performance by performing a MAC operation on the first sub-memory cell array 211 and a MAC operation on the second sub-memory cell array 212 in parallel and substantially at the same time. In addition, the memory device 200 does not include switches (i.e., resistors) between the first and second regulators 2511 and 2521 and the bit lines BL0 to BL3, which may suppress IR drops. In addition, the bit lines of each of the first and second sub-memory cell arrays 211 and 212 are shunted, which may further suppress IR drops.

In an embodiment, the memory device 200 may perform only one of the MAC operation for the first sub-memory cell array 211 and the MAC operation for the second sub-memory cell array 212.

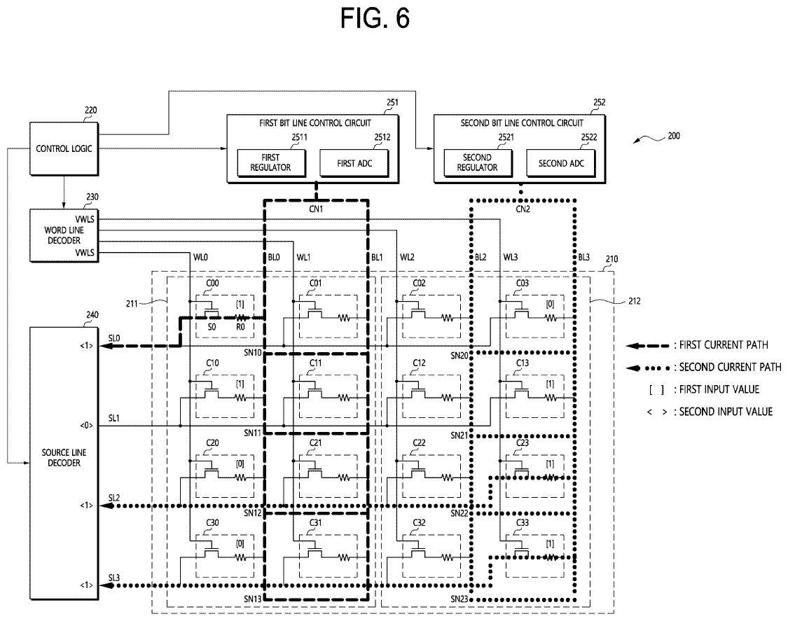

FIG. 6 is a diagram to illustrate how the memory device 200 of FIG. 5 may perform a MAC operation according to an embodiment of the present disclosure.

Referring to FIG. 6, the first target word line of the MAC operation on the first sub-memory cell array 211 may be the word line WL0, and the second target word line of the MAC operation on the second sub-memory cell array 212 may be the word line WL3. Accordingly, the first target memory cells in the first sub-memory cell array 211 may be memory cells C00 to C30 electrically coupled to the word line WL0, and the second target memory cells in the second sub-memory cell array 212 may be memory cells C03 to C33 electrically coupled to the word line WL3.

Based on the first and second input values, the first sub-memory cell array 211 may cause cell current to flow through the memory cell C00. Thus, the cumulative cell current amount in the first sub-memory cell array 211 may be equal to the amount of cell current in the memory cell C00, and the first analog-to-digital converter 2512 may output a digital value corresponding to the cumulative cell current amount as a first result of the MAC operation.

Based on the first and second input values, the second sub-memory cell array 212 may allow cell current to flow through each of the memory cells C23 and C33. Thus, the cumulative cell current amount of the second sub-memory cell array 212 is equal to the sum of the cell current amounts of the memory cells C23 and C33, and the second analog-to-digital converter 2522 may output a digital value corresponding to the cumulative cell current amount as a second result of the MAC operation.

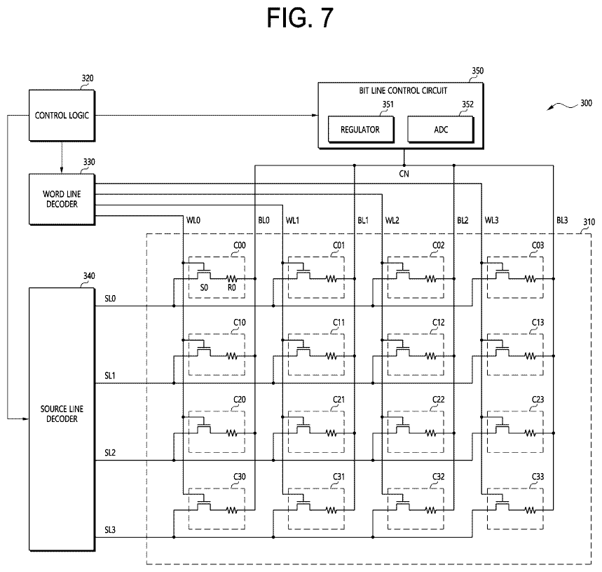

FIG. 7 is a block diagram illustrating a memory device 300 according to an embodiment of the present disclosure.

Referring to FIG. 7, the memory device 300 may be configured similarly to the memory device 100 of FIG. 1, except that the bit lines BL0 to BL3 are not shunted.

Thus, the memory device 300 does not include switches (i.e., resistors) between a regulator 351 and the bit lines BL0 to BL3, which may result in lower IR drops than if such switches are present. However, because the bit lines BL0 to BL3 are not shunted, in a MAC operation, current path may only be formed on a bit line corresponding to a target word line.

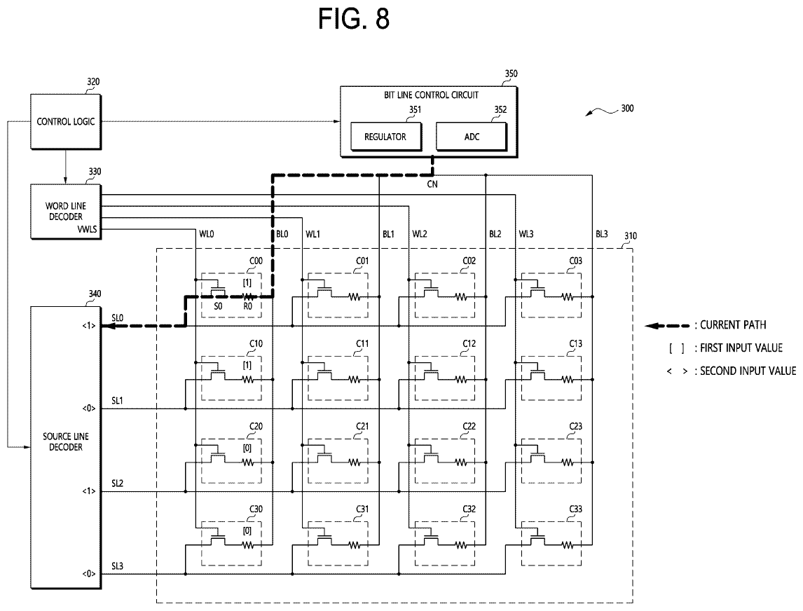

FIG. 8 is a diagram to illustrate how the memory device 300 of FIG. 7 performs a MAC operation according to an embodiment of the present disclosure.

Referring to FIG. 8, the MAC operation is for the same first input values and second input values as the embodiment of FIG. 3, but a current path to the source line SL0 may be formed only on the bit line BL0 and not on the bit lines BL1 to BL3.

A person skilled in the art to which the present disclosure pertains can understand that the present disclosure may be carried out in other specific forms without changing its technical spirit or essential features. Therefore, it should be understood that the embodiments described above are illustrative in all aspects, not limitative. The scope of the present disclosure is defined by the claims to be described below rather than the detailed description, and it should be construed that the meaning and scope of the claims and all changes or modified forms derived from the equivalent concept thereof are included in the scope of the present disclosure.

What is claimed is:

1. A memory device, comprising:
a memory cell array including a plurality of memory cells arranged in areas in which word lines and bit lines intersect with source lines, the word lines and the bit lines extending in a first direction and the source lines extending in the second direction, wherein memory cells along the first direction, among the plurality of memory cells, are electrically coupled to a same word line and a same bit line, memory cells along the second direction, among the plurality of memory cells, are electrically coupled to a same source line, and the bit lines are shunted at one or more shunt nodes; and
a regulator configured to apply a bit line voltage to a common node at which the bit lines are electrically coupled in common.

2. The memory device of claim 1, wherein the shunt nodes are spaced apart at regular distance intervals.

3. The memory device of claim 1, wherein the number of the shunt nodes is equal to the number of the source lines.

4. The memory device of claim 1, wherein the bit lines are electrically coupled to the common node without switches.

5. The memory device of claim 1, wherein each of the plurality of memory cells comprises:
a variable resistor element having one end electrically coupled to a respective bit line; and
a switch element operable in response to a voltage through a respective word line, the switch element being electrically coupled between the other end of the variable resistor element and a respective source line.

6. The memory device of claim 1, further comprising a source line decoder configured to apply voltages, corresponding to input values received from an external device, to the source lines, respectively.

7. The memory device of claim 6, wherein the source line decoder applies a first source line voltage to a source line when an input value corresponding to the source line is a first value and applies a second source line voltage to the source line when the input value corresponding to the source line is a second value.

8. The memory device of claim 1, further comprising a word line decoder configured to apply a selection voltage to a target word line, among the word lines, and configured to apply a non-selection voltage to remaining word lines.

9. The memory device of claim 1, further comprising an analog-to-digital converter configured to output a digital value corresponding to a cumulative cell current amount flowing through a sensing node electrically coupled to the common node.

10. The memory device of claim 9, wherein the regulator comprises:
an operational amplifier configured to output an output voltage in response to the bit line voltage and a voltage of the common node; and
an NMOS transistor electrically coupled between the sensing node and the common node, the NMOS transistor being operative in response to the output voltage.

11. A memory device, comprising:
a memory cell array including a plurality of memory cells arranged in areas in which word lines and bit lines intersect with source lines, the word lines and the bit lines extending in a first direction and the source lines extending in the second direction, wherein memory cells along the first direction, among the plurality of memory cells, are electrically coupled to a same word line and a same bit line, and memory cells along the second direction, among the plurality of memory cells, are electrically coupled to a same source line;
a first regulator configured to apply a bit line voltage to a first common node at which first bit lines of the bit lines are electrically coupled; and
a second regulator configured to apply the bit line voltage to a second common node at which second bit lines of the bit lines are electrically coupled.

12. The memory device of claim 11, wherein the first bit lines are shunted at one or more first shunt nodes, and the second bit lines are shunted at one or more second shunt nodes.

13. The memory device of claim 11, further comprising a word line decoder configured to apply a selection voltage to first and second target word lines, among the word lines, and configured to apply a non-selection voltage to remaining word lines,
wherein the first target word line is any word line corresponding to the first bit lines, and the second target word line is any word line corresponding to the second bit lines.

14. A memory device, comprising:
a memory cell array including a plurality of memory cells arranged in areas in which word lines and bit lines intersect with source lines, the word lines and the bit lines extending in a first direction and the source lines extending in the second direction, wherein memory cells along the first direction, among the plurality of memory cells, are electrically coupled to a same word line and a same bit line, and memory cells along the second direction, among the plurality of memory cells, are electrically coupled to a same source line; and
a control logic configured to perform a MAC operation on one or more first input values and one or more second input values by storing the first input values in one or more target memory cells electrically coupled to a target word line, among the word lines.

15. The memory device of claim 14, further comprising a source line decoder configured to, under control of the control logic, apply voltages corresponding to the second input values to the source lines, respectively.

16. The memory device of claim 15, wherein the source line decoder applies a first source line voltage to a source line when a second input value corresponding to the source line is a first value and applies a second source line voltage to the source line when the second input value corresponding to the source line is a second value.

17. The memory device of claim 14, further comprising a word line decoder configured to, under control of the control logic, apply a selection voltage to the target word line and configured to apply a non-selection voltage to remaining word lines.

18. The memory device of claim 14, further comprising an analog-to-digital converter configured to output a digital value corresponding to a cumulative cell current amount of the target memory cells.

19. The memory device of claim 14, further comprising a regulator configured to apply a bit line voltage to a common node at which the bit lines are electrically coupled in common, wherein the bit lines are shunted at one or more shunt nodes.
